(19) United States
(12) Patent Application Publication
(10) Pub. No.: US 2015/0359107 A1
(43) Pub. Date: Dec. 10, 2015

(54) ELECTRONIC MODULE WITH A PLASTIC-COATED ELECTRONIC CIRCUIT AND METHOD FOR THE PRODUCTION THEREOF

(71) Applicant: CONTI TEMIC MICROELECTRONIC GMBH, Nürnberg (DE)

(72) Inventors: MARTIN STEINAU, NUERNBERG (DE); THOMAS SCHMIDT, BURGLENGENFELD (DE); BERNHARD SCHUCH, NEUSITZ (DE)

(21) Appl. No.: 14/654,608

(22) PCT Filed: Nov. 11, 2013
(86) PCT No.: PCT/DE2013/200288

§ 371 Date: Jun. 22, 2015

(30) Foreign Application Priority Data
Dec. 20, 2012 (DE) 10 2012 112 738.7

(51) Int. Cl. H05K 3/28; H05K 7/20; H05K 3/00

(52) U.S. Cl. CPC H05K 3/284; H05K 3/0061; H05K 7/20854

(57) ABSTRACT

An electronic module for use as a control device in a motor vehicle, includes a plastic-coated electronic circuit with at least one organic HDI circuit carrier. The electronic circuit is disposed on a heat sink and electrically-conductive conductor structures are provided for electrically connecting the electronic circuit to electrical devices or components outside the electronic module. The circuit carrier is thermally and conductively connected to the heat sink, and the electronic circuit and the heat sink are coated in plastic in such a manner that only the rear side of the heat sink lying opposite the circuit carrier is at least partially free of plastic, and at least contact ends of the conductor structures, which make the electrical connection to the electrical devices or components outside the electronic module are free of plastic. A method for the production of the electronic module is also provided.

The invention relates to an electronic module with a plastic-coated electronic circuit as claimed in the preamble of claim 1, and to a method for the production thereof as claimed in claim 12.

In motor vehicle construction it has become customary in the meantime to integrate control units into the motor vehicle assembly to be controlled, in particular the engine or transmission. Primarily the transmission control units, as local control unit, form an extremely compact unit. In comparison with the conventional use of external control units, this arrangement has enormous advantages with regard to quality, costs, weight and functionality. In particular, this results in a considerable reduction of plug connections and lines, and thus of possible causes of failure.

The integration of the control unit into the transmission makes stringent requirements primarily of its thermal and mechanical loading capacity. Functionality has to be ensured both over a wide temperature range (approximately −40° C. to 150° C.), and in the case of extreme mechanical vibrations (up to 40 g). Since the control unit is surrounded by highly viscous and chemically aggressive transmission oil, stringent requirements are also made of the oil-tightness of the control unit.

The Patent Specification DE 197 51 095 C 1 describes such a local control unit in the transmission housing of a motor vehicle. The control unit comprises two housing parts connected to one another in an oil-tight manner, an electrical connection element being led through said housing parts, wherein the connection element connects the circuit carrier in the housing to electrical devices outside the housing.

US2008/0170372 A1 describes a control unit having a circuit carrier, onto which electronic components are arranged, and an electrical connection element for connecting the circuit carrier to its peripherals. The circuit carrier is arranged on a baseplate, which serves as a heat sink and dissipates heat from the circuit carrier. Plastic is molded around the circuit carrier, the connection element and the baseplate in such a way that the circuit carrier with its components is completely enclosed, but the majority of the rear side of the baseplate and the outer ends of the electrical connection element are free of plastic. This control unit can be mounted without a housing as a local control unit for example in a transmission.

The surfaces of the circuit carrier and of the baseplate are at least partly roughened. What is achieved by this surface roughness is that the enclosing plastic is intermeshed with the surfaces of the circuit carrier and the baseplate better than in the case of smooth surfaces. This is intended to prevent a situation in which, in the event of temperature fluctuations, owing to the different coefficients of expansion of the involved components of the control unit, in particular the connection of the electrical component to the circuit carrier is destroyed or the plastic acquires cracks or detaches from the circuit carrier or the baseplate and, for example, oil from the transmission can thus penetrate as far as the circuit carrier and damages the latter.

In US2008/0170372 A1 cited, the importance of the individual material characteristic figures is emphasized in the selection of the involved components of the control unit. In this regard, by way of example, the advantages of a ceramic printed circuit board compared with an organic printed circuit board are discussed in great detail. In this regard, in particular, the thermal conductivity of a ceramic printed circuit board is an order of magnitude higher than that of an organic printed circuit board. This is important with regard to the dissipation of the heat generated for example by a microcontroller on the circuit carrier.

One disadvantage when using a ceramic printed circuit board is primarily the high price, which is somewhat more than that of an organic printed circuit board. A further disadvantage of the arrangement described is that the production of the rough surface both for the circuit carrier and for the baseplate in each case constitutes an additional work step that increases the total costs of the control unit.

The use of a ceramic printed circuit board as circuit carrier furthermore has the disadvantage that the selection of the electrical components which can be mounted on it is restricted. In particular, either only power components such as, for example, power transistors as switching elements can be arranged on the ceramic circuit carrier or only signal producing and/or signal processing components such as, for example, microprocessors can be installed.

One example thereof is DE 100 13 255 A1, which describes a resin-encapsulated electronic device, wherein the microprocessor is arranged on a ceramic printed circuit board and the power semiconductor is arranged on a separate device.

WO 2011/072629 A1 describes a so-called HDI (High Density Interconnect) printed circuit board for use in a housing of a local control unit in a motor vehicle. HDI circuit carriers are specific organic multilayer printed circuit boards which are primarily distinguished by a good heat dissipation from the topmost printed circuit board layer, on which a heat-generating active component is arranged, for example, to the bottommost printed circuit board layer, which is thermally conductively connected to a heat sink [our own HDI application].

An HDI circuit carrier has vertical plated-through holes from one printed circuit board layer to the next which have both an electrically conductive function and a thermally conductive function. Said plated-through holes are designated as vertical interconnect access, hereinafter for short as via. Vias embodied as plated-through holes having a diameter of less than approximately 150 μm are also designated as microvias. Owing to the small diameter of the microvias, a relatively large number of contact-connections on a relatively small area of the circuit carrier is possible, as a result of which this type of circuit carrier is predestined for the mounting of unpackaged semiconductor components, so-called bare dies, which by their nature have a much narrower contact spacing than packaged components.

Therefore, it is an object of the invention to provide a plastic-coated electronic module for use as a control unit in a motor vehicle which guarantees both low material and low production costs and furthermore high process reliability, in particular oil-tightness, throughout the entire service life.

This object is achieved according to the invention by means of an electronic module comprising the features of claim 1.

The heart of the invention is that at least one organic so-called HDI circuit carrier with an electronic circuit comprising at least one electronic component is thermally conductively connected to a heat sink and the electronic circuit and the heat sink are coated with plastic in such a way that only the rear side of the heat sink situated opposite the circuit carrier, at least partly, and at least the contact ends of the conductor structures which serve for electrical connection to the electrical devices outside the electronic module are free of plastic.

The coating of the circuit carrier and of a part of the heat sink and of the conductor structures with plastic, in particular a thermosetting polymer, such as silicone, epoxy silicone, epoxy resin or phenolic resin, enables the same protection against damaging environment influences in the local environment as an expensive housing. In addition, unlike in the case of a control unit having a housing, the conductor structures for electrically connecting the electronic circuit to the electrical devices outside the electronic module do not have to be separately sealed and the plastic-free rear side of the heat sink can be mounted on a part of the transmission at which lower temperatures prevail, for the purposes of optimum heat dissipation.

The different coefficients of thermal expansion in particular of the plastic, of the circuit carrier, of the conductor structures and of the heat sink are ideally coordinated with one another in such a way that they are in each case of the order of magnitude of +/−15% in direct comparison, such that in the event of temperature fluctuations within the operating temperature range of approximately −40° C. to 150° C., for example, it is possible to prevent a situation in which cracks occur in the plastic itself or the plastic detaches from the circuit carrier or the baseplate and for instance oil from the transmission can thus penetrate as far as the circuit carrier and damage or even destroy the latter.

The use of an HDI circuit carrier with its particular arrangement and combination of vias and heat conducting layers of the different printed circuit board layers makes it possible for a power component having high heat generation and operating current intensities of up to approximately 80 A and at the same time a signal generating and/or processing component, such as an unpackaged microprocessor having very narrow contact spacings and comparatively low operating current intensities, to be used simultaneously on the topmost printed circuit board layer. By contrast, generally only current intensities of up to a maximum of 25 A can be realized on ceramic circuit carriers.

On account of their coefficients of thermal expansion (CTE for short) and their thermal conductivity, aluminum or copper or alloys thereof are particularly well suited as heat sink material for an organic HDI printed circuit board. They are also more cost-effective than specific composite materials such as e.g. AlSiC. A flat plate is particularly well suited as heat sink since it has a large area for heat dissipation and can easily be mounted on the housing of a transmission, for example.

The plate of the heat sink can also have a stepped portion, in particular at the edge of the plate. The stepped portion increases the contact area between the plate and the coating plastic and thus the creepage path for liquids and gases possibly penetrating into the electronic module. The creepage path extension can be implemented both by the stepped portion in the cross section of the heat sink and as an undercut into which plastic can penetrate in a targeted manner, wherein the undercut is arranged in particular such that it is optimally adapted to the shape filling behavior of the plastic in order to avoid air inclusions. Both creepage path extending measures can also occur in combination.

As electrically conductive conductor structures for electrically connecting an electronic component on the circuit carrier of the electronic circuit to electrical devices outside the electronic module, use is made of, as already mentioned, in particular at least one leadframe, a further printed circuit board or a flexible foil conductor. In this case, the leadframe or the flexible foil can be soldered, welded or adhesively bonded, for example, directly onto the circuit carrier. However, the electrical connection can also be produced indirectly for example by means of a bonding wire between circuit carrier and conductor structure.

Leadframe and printed circuit board are used primarily in the case of simply structured environments of the electronic module; the more expensive flexible foil conductors can be adapted to more complexly arranged environments.

The mechanical connection between circuit carrier and conductor structure is generally cohesive or force-locking. This function can be implemented by soldering, welding or adhesive bonding, or else sintering, sinter bonding, in particular as described further above in association with the electrical connection.

The coating plastic is advantageously filled with non-metallic, inorganic particles, such as SiO₂ or Al₂O₃, for example, since, on the one hand, they are electrically insulating in order to avoid short circuits of the electronic circuit and, on the other hand, they have a good thermal conductivity in order, in addition to the heat sink, to contribute to the dissipation of the heat arising on account of the power loss of the electronic components. Other fillers such as AlN, BN or SiC would also be conceivable, in principle, since they have an even higher thermal conductivity than the oxides mentioned, but for cost reasons and on account of their high hardness it is actually very unlikely that they can be used economically.

Since the contact area of plastic and circuit carrier is generally smaller than the contact area of circuit carrier and heat-dissipating heat sink, the glass transition point of the plastic is preferably at least equal to or greater than that of the circuit carrier. The glass transition point of a material is a measure of the maximum permissible operating temperature, particularly in the case of carbon-based thermosetting plastics. In particular, the coefficient of thermal expansion of the material increases by four- to five-fold starting from the glass transition temperature, which would have adverse effects on the construction of the electronic module.

In principle, it is of importance for the glass transition temperature of the coating polymer to be above the use temperature of the electronics. This is because delaminations on the circuit carrier can occur as a result of the change in the CTE during the thermal cycle.

In order to achieve a particularly good thermal linking of the circuit carrier to the heat sink, the circuit carrier is connected to the heat sink in particular by means of a thermally conductive adhesive material, e.g. by means of a thermally conductive adhesive filled with inorganic particles, or a thermally conductive foil material by means of lamination.

A further object of the invention is to provide a method for producing a plastic-coated electronic module for use as a control unit in a motor vehicle which guarantees both low material and low production costs and furthermore high process reliability, in particular oil-tightness, throughout the entire service life.

This object is achieved according to the invention by means of a method comprising the features of claim 12.

In the case of the method according to the invention for producing the electronic module according to the invention, firstly the following components are provided:
an organic HDI circuit carrier suitable for bare die mounting, that is to say for the mounting of unpackaged components, having at least one electronic component,
at least one electrically conductive conductor structure for electrically connecting the electronic circuit to electrical devices outside the electronic module,
a heat sink,
a mold.

An electrical connection between the at least one electronic component of the electronic circuit and corresponding electrically conductive conductor structures is subsequently produced.

In particular, at least one leadframe, a further printed circuit board or a flexible foil conductor or a combination thereof can be used as electrically conductive conductor structures. In this case, the leadframe or the flexible foil can be soldered, welded or adhesively bonded, for example, on the one hand directly onto the circuit carrier. This direct electrically conductive connection generally also serves as mechanical connection between electronic circuit and conductor structure.

However, the electrical connection can also be produced indirectly for example by means of a bonding wire composed of gold, silver or else copper, for example, between circuit carrier and conductor structure.

In a further step, the circuit carrier is thermally conductively connected to the heat sink. This is advantageously carried out by means of a thermally conductive adhesive material, e.g. a thermally conductive adhesive. The order of the last two steps is any desired order.

Afterward, the electronic circuit with the heat sink is inserted into a mold and plastic is molded around said electronic circuit with heat sink. The plastic is preferably a thermosetting polymer such as, for example, silicone, epoxy silicone, epoxy resin or phenolic resin, which can be filled with inorganic particles.

After plastic has been molded around the electronic circuit and the heat sink, said electronic circuit and heat sink are coated with plastic in such a way that only the rear side of the heat sink situated opposite the circuit carrier is at least partly free of plastic. The free area of the rear side of the heat sink is then available for dissipating the heat from the electronic module.

Besides part of the rear side of the heat sink, the contact ends of the conductor structures which serve for electrical connection to the electrical devices outside the electronic module also remain free of plastic during the molding process.

The molding method used can be, in particular, so-called transfer molding, wherein plastic is forced into the mold and cures under heat and pressure. Compared with other methods, e.g. compression molding, this method affords the possibility of molding around even electronics having a complex circuit layout and components of greatly different sizes, without air inclusions. In principle, thermosetting plastic injection molding would also be conceivable.

Significantly higher pressures arise in this method, however, and can have the effect that, in particular, the fine gold bonding wires are scattered or torn away.

In the following description, the features and details of the invention are explained in greater detail on the basis of exemplary embodiments in association with the accompanying drawings. In this case, features and relationships described in individual variants are applicable, in principle, to all the exemplary embodiments. In the drawings:

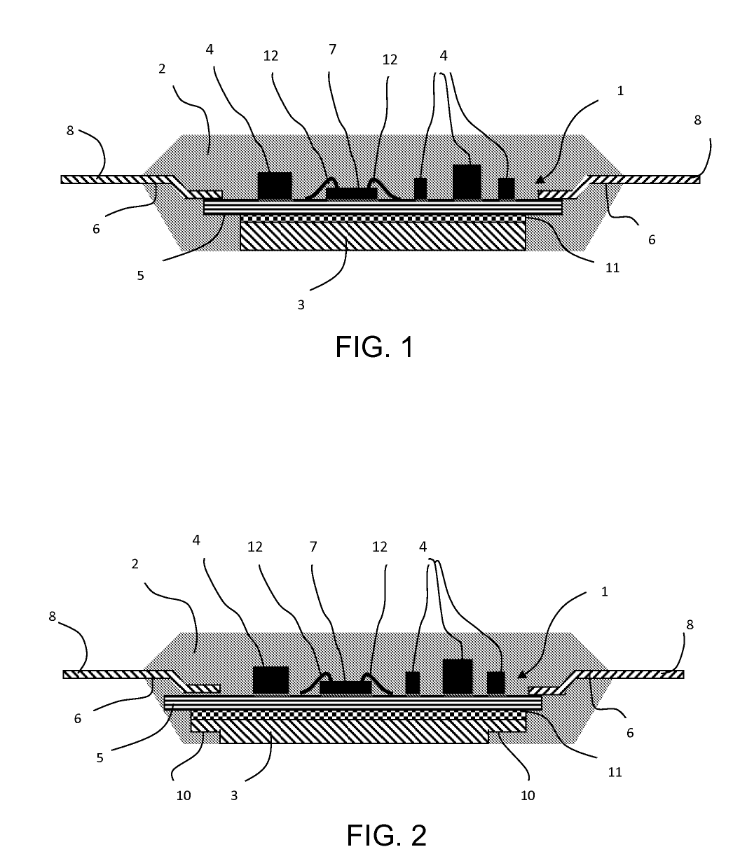

FIG. 1 shows an electronic module having a heat sink and a direct connection between circuit carrier and conductor structure,

FIG. 2 shows an electronic module as in FIG. 1 having a heat sink having a stepped portion,

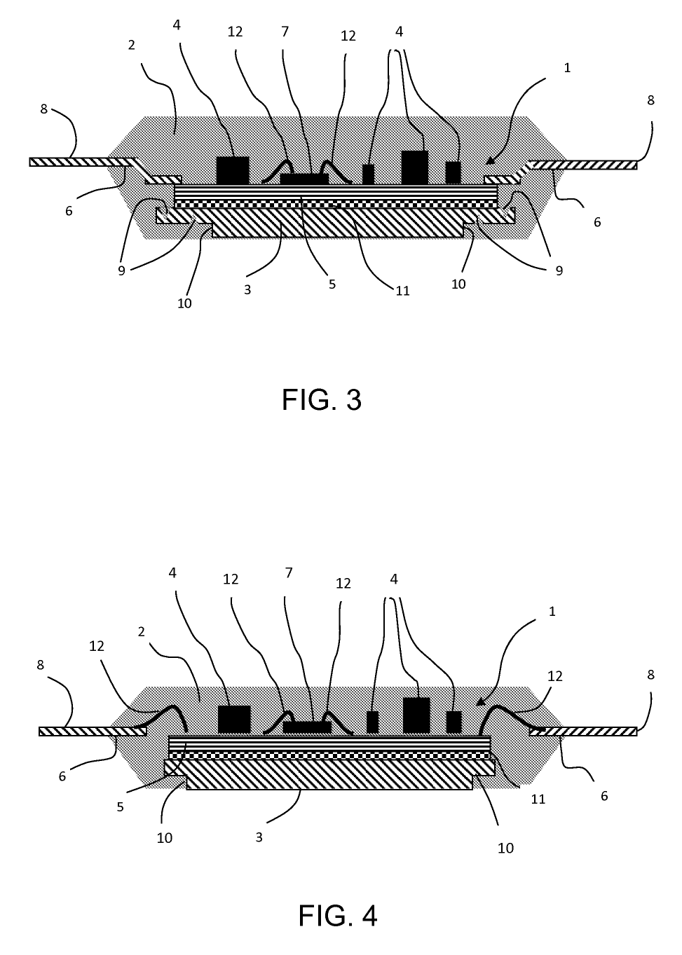

FIG. 3 shows an electronic module as in FIG. 1 having a heat sink having a stepped portion and an undercut,

FIG. 4 shows an electronic module having a stepped portion on the heat sink and a bonding wire between circuit carrier and conductor structure as indirect electrical connection, and

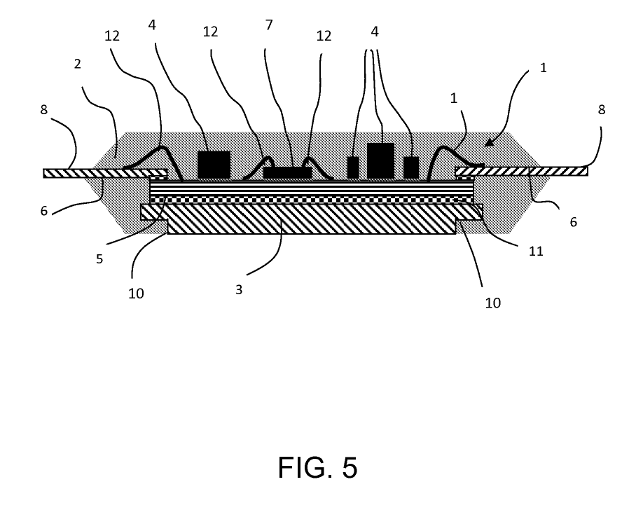

FIG. 5 shows an electronic module having a stepped portion on the heat sink and a bonding wire between circuit carrier and conductor structure, wherein the conductor structure is connected to the circuit carrier in a manner that is not electrically conductive.

FIG. 1 shows an electronic module for use as a control unit in a motor vehicle, having an electronic circuit 1 coated with plastic 2, said electronic circuit being arranged on a heatsink 3. The electronic circuit 1 comprises an organic HDI (High Density Interconnect) circuit carrier 5, on which electronic components 4, 7 are mounted.

The known structural features of an HDI printed circuit board are explained in greater detail below.

An HDI printed circuit board 5 is a specific multilayer printed circuit board. The printed circuit board layers in each case comprise at least one heat conducting layer, in particular composed of copper, applied to the electrically insulating base material composed of glass fiber reinforced plastic. A plurality of vias running in the z-direction perpendicularly to the printed circuit board layers are provided in this case.

Via (=Vertical Interconnect Access), also called layer changers, denotes a vertical plated-through hole which electrically and thermally connects at least two printed circuit board layers of a multilayer printed circuit board 5.

Blind via denotes a via embodied as a blind hole with a through contact which connects in particular the topmost or bottommost printed circuit board layer to at least one inner printed circuit board layer of a multilayer printed circuit board 5.

Buried via denotes a via which is arranged in the interior of a multilayer printed circuit board 5 and connects at least two inner printed circuit board layers.

Vias embodied as plated-through holes having a diameter of less than approximately 150 μm are also designated as microvias.

Vias which serve primarily for improving the heat transfer through a printed circuit board 5 are also designated as thermal vias.

The vias connect the heat conducting layers of different printed circuit board layers in such a way that the vias and the heat conducting layers of the printed circuit board layers form a heat conducting bridge from the topmost printed circuit board layer to the bottommost printed circuit board layer. In this case, the heat conducting layers simultaneously serve as electrical conductor.

In particular, a total surface area of all the heat conducting layers of at least one printed circuit board layer is greater than a total surface area of all the heat conducting layers of an overlying printed circuit board layer. In this case, the heat conducting bridge formed by the vias and heat conducting layers is widened from at least one printed circuit board layer to an underlying printed circuit board layer since the total surface area of all the heat conducting layers of at least one printed circuit board layer is greater than a total surface area of all the heat conducting layers of an overlying printed circuit board layer. As a result, the area that is effective for heat transfer is advantageously enlarged and the thermal resistance of the entire printed circuit board 5 is reduced since the thermal resistance is at least approximately proportional to the reciprocal of the area that is effective for heat transfer.

Especially in the case of an HDI printed circuit board, the topmost printed circuit board layer is connected to at least the nearest inner printed circuit board layer in the z-direction perpendicularly to the printed circuit board layers at least in part by means of blind vias embodied as microvias having a small diameter. A higher number of vias per area is possible as a result. Besides an increased current-carrying capacity, this results in particular in an improved heat dissipation, especially from active electronic components 4, 7 that emit heat. The higher number of vias per area as a result of the use of microvias primarily also makes it possible, however, that especially unpackaged electronic components 4, so-called bare dies, can be mounted on the topmost printed circuit board layer, the contact spacings of said unpackaged electronic components being somewhat smaller than those of packaged components 7.

In particular, a multifunctional additional metallization comprising a layer sequence composed of e.g. nickel, palladium and gold is applied at least to the heat conducting layers of the printed circuit board layers. Connection techniques for populating the printed circuit board 5 with unpackaged components 4 together with packaged components 4 are possible as a result. For this purpose, the additional metallization is applied to the outer copper surface of the heat conducting layers, wherein the additional metallization is simultaneously suitable for mounting processes in particular by means of soldering technology, silver conductive adhesive bonding, etc. for unpackaged active components 4 and connection techniques such as e.g. wire bonding using gold wire and/or aluminum wire in particular for packaged passive components 7.

As already mentioned, in particular the heat conducting layers of the printed circuit board layers and the walls of the vias are coated with copper and additionally provided with a multifunctional metallization composed of NiPdAu. This also primarily contributes to the current-carrying capacity of this HDI printed circuit board 5 being up to 50 A or more. By contrast, the maximum current-carrying capacity of thick-film ceramic printed circuit boards is approximately 25 A.

When the electronic module comprising an electronic circuit 1 coated with plastic 2 on a heat sink 3 is used as control unit in a motor vehicle, what is essentially of importance is that the different coefficients of thermal expansion of the individual components are ideally coordinated with one another in such a way that they are in each case of the order of magnitude of +/−15% in direct comparison. What is achieved as a result is that, in the event of temperature fluctuations, the situation is prevented in which cracks occur in the plastic itself or the plastic detaches from the circuit carrier 5 or the heat sink 3 and, for instance, oil from the transmission can thus penetrate as far as the circuit carrier 5 and damage or even destroy the latter.

The coefficient of thermal expansion CTE of a circuit carrier such as the HDI printed circuit board 5 is in the range of 18-20 ppm/° C. The CTE of copper is 16 ppm/° C., and that of aluminum is 23 ppm/° C. Therefore, these two materials are particularly well suited as heat sink 3 for an HDI printed circuit board 5 since they can be connected to one another in a manner virtually free of stress.

Compared with iron, for example, the CTE of which is 12 ppm/° C. and which is thus more suitable as heat sink material for a ceramic printed circuit board with 5-7 ppm/° C., copper and aluminum additionally have the advantage over iron that their thermal conductivity of 200 W/mK for aluminum and 400 W/mK for copper is 3-5 times higher than that of iron, which is 70 W/mK.

The conductor structure 6 can be embodied in particular as a leadframe composed of copper, having a CTE of 16 ppm/° C., as an additional printed circuit board composed of glass fiber reinforced plastic having a CTE of 18-20 ppm/° C., or a flexible foil conductor comprising a composite composed of a polyimide and a copper foil having a CTE in the range of 16-18 ppm/° C. The conductor structure 6 is directly connected to the circuit carrier 5 in FIG. 1. This connection can be produced by welding, soldering or adhesive bonding and has the function both of an electrical connection and of a mechanical connection.

The coating plastic 2 consists, in particular, of a thermosetting polymer such as silicone, epoxy silicone, epoxy resin or phenolic resin. The CTE of these materials here is in the range of 14-19 ppm/° C., wherein the range can be set by different admixtures of the inorganic fillers, e.g. SiO₂.

These plastic materials are thus suitable on account of their CTE for coating the circuit carrier 3, the conductor structure 6 and at least part of the heat sink 3 such that, in the event of temperature fluctuations, cracks do not occur in the plastic 2 itself or the plastic 2 does not detach from the circuit carrier 5 or the heat sink 3. However, the use of a thermoplastic polymer would also be conceivable.

The coating with plastic 2 enables the same protection against damaging environmental influences in the local environment as a more expensive housing. Furthermore, the soft potting—otherwise customary in control unit housings—of the electronic circuit 1 with silicone gel and/or silicone lacquer as protection against, for example, ingress of harmful gases is obviated by the encapsulation with plastic 2.

In addition, unlike in the case of a control unit having a housing, the conductor structure 6 for electrically connecting the electronic circuit 1 to the electrical devices outside the electronic module does not have to be separately sealed in the housing wall.

The operating temperature of the plastic 2 is generally somewhat higher than that of the circuit carrier 5 since, in particular, the contact area between plastic 2 and circuit carrier 5 is smaller than the contact area between the circuit carrier 5 and the heat-dissipating heat sink 3. Therefore, the glass transition point of the plastic 2 is preferably at least equal to or greater than that of the circuit carrier 5, wherein the glass transition point of a material is a measure of the maximum permissible operating temperature.

The plastic-free rear side of the heat sink 3 can be mounted on a part of the transmission (not shown here) at which lower temperatures prevail, for the purpose of optimum heat dissipation.

FIG. 2 shows an electronic module in which the heat sink 3 has a stepped portion 10 at the edge. The stepped portion 10 can, but need not, be arranged circumferentially at the edge of the heat sink 3. The stepped portion 10 increases the contact area between the heat sink 3 and the coating plastic 2 and thus the creepage path for liquids and gases possibly penetrating into the electronic module from outside and thus reduces the probability of failure of the module.

As an alternative to the stepped portion 10, the creepage path extension can also be embodied as an undercut 9 into which plastic 2 can penetrate in a targeted manner. Both creepage path extending measures can also occur in combination, as shown in FIG. 3.

In FIG. 4, the conductor structure 6 is electrically conductively connected to the circuit carrier 5 indirectly by means of a bonding wire 12, for example a Cu bonding wire, the CTE of which, as described further above, is in the range of the plastic 2 and is thus coated by the latter in a manner substantially free of stress.

FIG. 5 shows an electronic module in which the conductor structure 6 is connected to the circuit carrier 5 in a manner that is not electrically conductive, for example is adhesively bonded to said circuit carrier. The electrically conductive connection between circuit carrier 5 and conductor structure 6 is produced by means of a bonding wire 12.

Through suitable selection of the materials of its individual components, the electronic module according to the invention is largely insensitive to temperature fluctuations, thus substantially free of stress and hence reliably impermeable throughout its entire service life. The compact construction of the electronic module guarantees a space-saving installation, wherein the electronic module can also be installed like a plug in particular as a result of a suitable shape of the heat sink. In addition, during the production of the electronic module, the same mold can advantageously be used for different electronic circuits.

Last but not least, the complete encapsulation of the electronic module offers protection against plagiarization and/or protection against third-party manipulation.

### LIST OF REFERENCE SIGNS

1 Electronic circuit
2 Plastic
3 Heat sink
4 Unpackaged electronic component
5 Circuit carrier
6 Electrically conductive conductor structure
7 Packaged electronic component
8 Open contact ends of the conductor structure
9 Undercut
10 Stepped portion
11 Thermally conductive adhesive
12 Bonding wire

1-16. (canceled)

17. An electronic module for use as a control unit in a motor vehicle, the electronic module comprising:
a heat sink; and
an electronic circuit disposed on said heat sink, said electronic circuit including:
at least one organic HDI (High Density Interconnect) circuit carrier for bare die mounting, said at least one circuit carrier being thermally conductively connected to said heat sink, defining a rear side of said heat sink disposed opposite said at least one circuit carrier;
at least one electronic component disposed on said at least one circuit carrier; and
electrically conductive conductor structures having contact ends for electrically connecting said at least one electronic component to electrical devices outside the electronic module;
said electronic circuit and said heat sink being coated with plastic leaving only said rear side of said heat sink at least partly free of plastic and leaving at least said contact ends of said conductor structures free of plastic.

18. The electronic module according to claim 17, wherein said plastic, said at least one circuit carrier, said conductor structures and said heat sink have coefficients of thermal expansion being coordinated with one another and being on the order of magnitude of +/−15% in comparison to each other.

19. The electronic module according to claim 17, wherein said at least one electronic component includes more than one electronic component including a power component and at least one of a signal generating or processing component simultaneously mountable on said at least one circuit carrier.

20. The electronic module according to claim 17, wherein said heat sink is a flat metallic plate.

21. The electronic module according to claim 20, wherein said flat metallic plate is formed of aluminum or copper.

22. The electronic module according to claim 20, wherein said heat sink is a flat plate having at least one stepped portion.

23. The electronic module according to claim 20, wherein said heat sink is a flat plate having at least one undercut.

24. The electronic module according to claim 17, wherein said electrically conductive conductor structures are a leadframe, a printed circuit board or foil conductors.

25. The electronic module according to claim 17, wherein said plastic is a thermosetting polymer.

26. The electronic module according to claim 25, wherein said thermosetting polymer is silicone, epoxy silicone, epoxy resin or a phenolic resin.

27. The electronic module according to claim 24, wherein said plastic is filled with inorganic particles.

28. The electronic module according to claim 27, wherein said inorganic particles are SiO₂ particles.

29. The electronic module according to claim 17, wherein said plastic has a glass transition point being equal to or greater than a glass transition point of said at least one circuit carrier.

30. The electronic module according to claim 17, wherein said at least one circuit carrier is thermally conductively connected to said heat sink by a thermally conductive adhesive material.

31. A method for producing an electronic module for use as a control unit in a motor vehicle, the method comprising the following steps:
providing an organic HDI circuit carrier being suitable for bare die mounting and having at least one electronic component of an electronic circuit;
providing electrically conductive conductor structures having contact ends for electrically connecting the at least one electronic component to electrical devices outside the electronic module;
providing a heat sink;
providing a mold;
producing an electrical connection between the at least one electronic component and a corresponding electrically conductive conductor structure;
producing a thermally conductive connection between the circuit carrier and the heat sink defining a rear side of the heat sink disposed opposite the circuit carrier;
inserting the electronic circuit with the heat sink into the mold;
molding plastic around the electronic circuit with the heat sink by coating the electronic circuit and the heat sink with plastic, leaving only the rear side of the heat sink at least partly free of plastic and leaving at least the contact ends of the conductor structures free of plastic; and
curing the plastic.

32. The method according to claim 31, which further comprises producing the electrical connection between the at least one electronic component of the electronic circuit and the electrically conductive conductor structure directly by soldering, welding or adhesively bonding the conductor structure onto the circuit carrier.

33. The method according to claim 31, which further comprises producing the electrical connection between the at least one electronic component of the electronic circuit and the electrically conductive conductor structure indirectly by wire bonding.

34. The method according to claim 31, which further comprises producing a thermally conductive connection between the circuit carrier and the heat sink by using a thermally conductive adhesive material.

35. The method according to claim 31, which further comprises carrying out the step of molding plastic around the electronic circuit with the heat sink by transfer molding.
